(19) United States
(12) Patent Application Publication
(10) Pub. No.: US 2009/0068823 A1
(43) Pub. Date: Mar. 12, 2009

(54) Plasma Ion Doping Method and Apparatus

(75) Inventors: Soo Jin Hong, Gyeonggi-do (KR); Si-Young Choi, Gyeonggi-do (KR); Tai-Su Park, Gyeonggi-do (KR); Jin-Wook Lee, Gyeonggi-do (KR); Jong-Hoon Kang, Gyeonggi-do (KR); Mi-Jin Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/145,914

(22) Filed: Jun. 25, 2008

(30) Foreign Application Priority Data
Jun. 27, 2007 (KR) 2007-0063805

(51) Int. Cl. H01L 21/02; H01J 37/08

(52) U.S. Cl. 438/513; 250/492.21; 257/E21.143

(57) ABSTRACT

In plasma ion doping operations, a wafer is positioned on a susceptor within a reaction chamber and an ion doping source gas is plasmalyzed in an upper part of the reaction chamber above a major surface of the wafer while supplying a control gas into the reaction chamber in a lower part of the reaction chamber opposite the major surface of the wafer to thereby dope ions into the major surface of the wafer. The ion doping source gas may comprise at least one halide gas, and the control gas may comprise at least one depositing gas, such as a silane gas. In further embodiments, a diluent gas, such as an inert gas, may be supplied to the reaction chamber while supplying the ion doping source gas and the control gas. Related plasma ion doping apparatus are described.

### CROSS-REFERENCE TO RELATED APPLICATION

This application claims priority from Korean Patent Application No. 10-2007-0063805 filed on Jun. 27, 2007 in the Korean Intellectual Property Office, the disclosure of which is incorporated herein by reference in its entirety.

### FIELD OF THE INVENTION

The present invention relates to semiconductor processing methods and apparatus and, more particularly, to plasma ion doping methods and apparatus.

### BACKGROUND OF THE INVENTION

In a plasma ion doping method, atoms are ionized into a plasma state and used to dope a substrate. Compared to ion beam implantation techniques that are widely used, plasma ion doping can dope atoms to an ultra shallow depth, to a high concentration, and in a three-dimensional (3D) profile. In addition, plasma ion doping may provide greater productivity, as its processing speed may be far greater than ion beam implantation. Hence, the plasma ion doping method is gaining popularity for use in a nanoscale semiconductor processes in which a precise ion doping profile is desired.

A halide gas is often used in plasma ion doping. For example, a fluoride gas containing fluorine (F) and a chloride gas containing chlorine (Cl) are known to have generally superior doping effects. Due to its high reactivity, a halide gas may etch a wafer. In order to control etching of the wafer, a depositing gas, such as SiH₄, Si₂H₆, Si₃H₈ or Si₂Cl₂H₂, may be used with the halide gas.

However, if the depositing gas is used together with a source gas for plasma ion doping, an unwanted film may be formed on a target film due to the depositing gas. The unwanted film may remain on the wafer even after a plasma ion doping process is terminated and may have a high resistance due to a low ion doping concentration. Consequently, the unwanted film may degrade the performance of a semiconductor device formed using such a process. Furthermore, the unwanted film may not be easily removed. If processes are performed in order to remove the unwanted film, other films may be damaged, thereby producing undesirable results.

Therefore, there is a need for plasma ion doping processes and apparatus that may reduce or prevent deterioration of the performance of a semiconductor device due to formation of unnecessary films.

### SUMMARY OF THE INVENTION

Some embodiments of the present invention provide plasma ion doping methods in which a wafer is mounted on a susceptor within a reaction chamber and an ion doping source gas is plasmalyzed in an upper part of the reaction chamber above a major surface of the wafer while supplying a control gas into the reaction chamber in a lower part of the reaction chamber opposite the major surface of the wafer to thereby dope ions into the major surface of the wafer. The ion doping source gas and control gas may be supplied in the presence of an electric field directed substantially perpendicular to the major surface of the wafer. The ion doping source gas may include at least one halide gas, and the control gas may include at least one depositing gas, such as a silane gas. In further embodiments, a diluent gas, such as an inert gas, may be supplied to the reaction chamber while supplying the ion doping source gas and the control gas. The diluent gas may be supplied to the upper part of the reaction chamber.

According to additional embodiments of the present invention, the control gas is flowed horizontally across the major surface of the wafer. For example, the control gas may be flowed in a sheath region. The control gas may be radially or spirally flowed across the major surface of the wafer.

In further embodiments of the present invention, plasma ion doping methods include mounting a wafer on a susceptor within a reaction chamber and plasmalyzing an ion doping source gas supplied to the reaction chamber in an upper part of the reaction chamber above a major surface of the wafer while flowing a control gas laterally across the major surface of the waver to thereby dope ions into the wafer. The control gas may be flowed into a plasma region, for example, into a sheath region. In additional embodiments, plasmalyzing an ion doping source gas supplied to the reaction chamber in an upper part of the reaction chamber above a major surface of the wafer while flowing a control gas laterally across the major surface of the waver to thereby dope ions into the wafer includes plasmalyzing the ion doping source gas while flowing the control gas laterally across the major surface of the waver and supplying a diluent gas to the upper part of the reaction chamber.

Further embodiments provide plasma ion doping apparatus including a reaction chamber, a susceptor disposed in the reaction chamber and configured to hold a wafer, a shower head disposed in an upper part of the reaction chamber and configured to supply a plasma ion doping source gas above a major surface of a wafer mounted on the susceptor and lower gas inlets configured to supply a control gas laterally onto a wafer mounted on the susceptor. The apparatus may further include lateral gas inlets configured to flow a gas across the major surface of a wafer mounted on the susceptor. The lateral gas inlets may be disposed above the susceptor and may be radially disposed around the susceptor.

### BRIEF DESCRIPTION OF THE DRAWINGS

The above and other features and advantages of the present invention will become more apparent by describing in detail, preferred embodiments thereof with reference to the attached drawings in which:

FIG. 1 is a schematic diagram illustrating a plasma ion doping apparatus and operations thereof according to some embodiments of the present invention;

FIGS. 2A and 2B are diagrams illustrating plasma ion doping operations according to further embodiments of the present invention;

FIGS. 3A through 3D are illustrations of various gas supply methods according to some embodiments of the present invention;

FIG. 4 is a schematic diagram illustrating a plasma ion doping apparatus according to additional embodiments of the present invention; and

FIG. 5 is a diagram illustrating various arrangements of gas inlets included in a plasma ion doping apparatus according to some embodiments of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their description will be omitted.

Embodiments of the invention are described herein with reference to plan and cross-section illustrations that are schematic illustrations of idealized embodiments of the invention. As such, variations from the shapes of the illustrations as a result, for example, of manufacturing techniques and/or tolerances, are to be expected. Embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

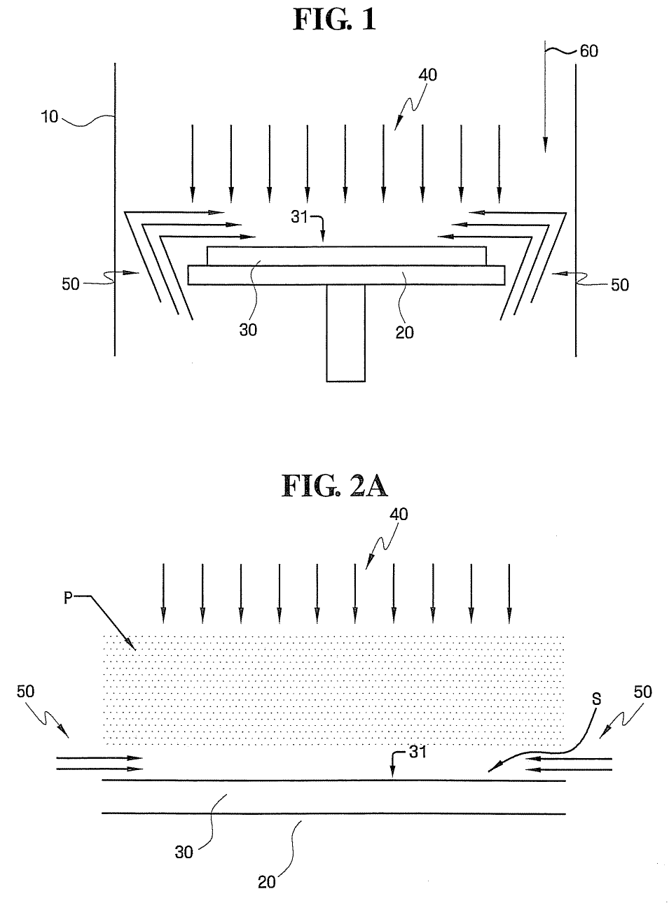

Hereinafter, plasma ion doping methods and apparatus according to some embodiments of the present invention will be described with reference to the attached drawings. Referring to FIG. 1, a wafer 30 is mounted on a susceptor 20 in a reaction chamber 10 of the plasma ion doping apparatus. An ion doping source gas 40 is injected into the reaction chamber 10 in a downward direction toward a major surface 31 of the wafer 30 in the reaction chamber 10. In addition, a control gas 50 is injected into the reaction chamber 10 from below the wafer 30 and/or from lateral directions with respect to the wafer 30.

The ion doping source gas 40 may contain ions for doping the wafer 30 and may include, for example, a halogenated gas. For example, the ion doping source gas 40 may contain one or more elements that belong to group III or V of a periodic table, such as boron (B), phosphorous (P) or arsenic (As). The ion doping source gas 40 may include a halide gas that contains a halogen gas such as fluorine, chlorine or bromine. For example, the ion doping source gas 40 may be include one or more of BF₃, BCl₃, B₂H₆, AsF₅, PF₂, CF₄, SiF₄, and HBr. Other types of gases may be used in combination with and/or instead of these gases. In plasma ion doping according to various embodiments of the present invention, when two or more gases are combined, they do not necessarily need to contain ions of the same polarity. Ions may have different doping profiles, even when they are doped simultaneously, due to their different mass and diffusion mobility.

In the illustrated embodiments, the ion doping source gas 40 is injected into the reaction chamber 10 of the plasma ion doping apparatus at an upper part of the reaction chamber 10 and plasmalyzed. The plasmalyzed ion doping source gas 40 is moved toward the susceptor 20 by an electric field 60 that is directed substantially perpendicular to the major surface 31 of the wafer 30. The plasmalyzed ion doping source gas 40 reacts with the wafer 30, such that ions from the plasmalyzed ion doping source gas 40 are doped into the major surface 31 of the wafer 30. As a result, conductive regions are formed in the wafer 30. These conductive regions may serve, for example, as junctions or signal transmission lines.

The control gas 50 is injected from below or from a direction lateral to the susceptor 20 on which the wafer 30 is mounted. In FIG. 1, the control gas 50 is injected from below the wafer 30. For example, the control gas 50 may be injected through an injection pipe from a direction lateral to the wafer 30.

Because the ion doping source gas 40 is injected from above the wafer 30, it may be relatively more affected by the electric field 60 than the control gas 50. Therefore, the control gas 50 may be relatively less reactive with the wafer 30 than the ion doping source gas 40. Consequently, ions may be doped into the wafer 30 in a stable manner.

If, like the ion doping source gas 40, the control gas 50 were to be injected into the reaction chamber 10 from the upper parts thereof, the control gas 50 might more strongly react with the wafer 30 due to the strong electric field 60. If this were the case, the film formed by the control gas 50 might be very dense, and it might be difficult to control the degree of blocking ions that are being doped. In addition, it might be difficult to remove the film after the plasma ion doping process is terminated, and other films might be damaged in attempts to remove the film. In contrast, in the illustrated embodiments, a film deposited by the control gas 50 may be relatively porous, thin or sparse. Therefore, the degree of blocking ion doping may be relatively low, and the film may be more easily removed.

In the illustrated embodiments, SiH₄ is used as the control gas 50. However, it will be understood that the present invention is not limited to the use of SiH₄ as a control gas. Because a purpose of the control gas 50 is to control reactivity of the ion doping source gas 40, other depositing gases (for example, Si₂Cl₂H₂, SiF₄ and silane type gases, such as Si₂H₆ and Si₃H₈) or diluent gases (for example, elements that belong to group 0 of the periodic table, such as He, Ne, Ar, Xe, etc.) may also be used in further embodiments of the present invention.

In the illustrated embodiments, the ion doping source gas 40 may contain a diluent gas, and the control gas 50 may contain a depositing gas, a diluent gas, or both. In some embodiments, each of the ion doping source gas 40 and the control gas 50 may contain a combination of three or more types of gases.

Plasma ion doping according to some embodiments of the present invention may be performed by independently injecting and flowing a diluent gas. In such embodiments, the diluent gas may be injected into the reaction chamber 10 in a downward, upward or lateral direction. While embodiments described herein include a control gas 50 containing a diluent gas, it will be understood that the control gas 50 need not contain a diluent gas and that a diluent gas may be separately supplied.

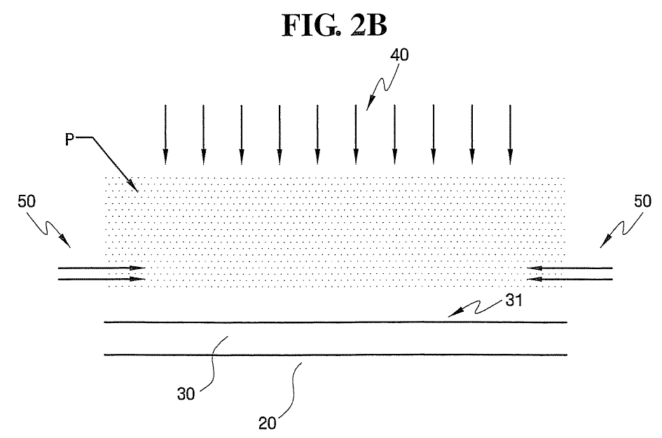

FIG. 2A is a diagram for explaining plasma ion doping according to further embodiments of the present invention. Referring to FIG. 2A, a wafer 30 is mounted on a susceptor 20. An ion doping source gas 40 is supplied to a plasma region P above a major surface 31 of the wafer 30. A control gas 50 is supplied to a sheath region S between the plasma region P and the major surface 31 of the wafer 30. The ion doping source gas 40 is plasmalyzed after passing through the plasma region P, which may cause the ion doping source gas 40 to react relatively strongly with the wafer 30. On the other hand, the control gas 50 does not pass through the plasma region P and thus may react relatively weakly with the wafer 30. Therefore, a deposited film formed by the control gas 50 reacting with the wafer 30 may be relatively porous, thin or sparse due to relatively low reactivity of the control gas 50.

In the illustrated embodiments, the control gas 50 may flow from directions lateral to the wafer 30 and onto a surface thereof. The ion doping source gas 40 may contain a diluent gas, and the control gas 50 may contain a depositing gas, a diluent gas, or both. In some embodiments, each of the ion doping source gas 40 and the control gas 50 may contain a combination of three or more types of gas.

FIG. 2B is a diagram for explaining plasma ion doping according to additional embodiments of the present invention. Referring to FIG. 2B, a wafer 30 is mounted on a susceptor 20. An ion doping source gas 40 is supplied to a plasma region P in a downward direction toward a major surface 31 of the wafer 30. A control gas 50 is supplied to the plasma region P from lateral directions. Because the ion doping source gas 40 is supplied from the upper parts of the plasma region P, it may be strongly affected by an electric field directed substantially perpendicular to the major surface 31 of the wafer 30. Therefore, the ion doping source gas 40 may react relatively strongly with the wafer 30 in comparison with the control gas 50. Because the control gas 50 is supplied from the lateral directions, it may be less affected by the electric field. Therefore, the control gas 50 may react relatively less strongly with the wafer 30 than the ion doping source gas 40.

In the illustrated embodiments, the ion doping source gas 40 may contain, for example, a diluent gas, and the control gas 50 may contain, for example, a depositing gas, a diluent gas, or both. In some embodiments, each of the ion doping source gas 40 and the control gas 50 may contain a combination of three or more types of gases.

In various embodiments of the present invention, because a deposited film formed by a deposition control gas 50 may be made porous, thin or sparse, a separate etching process for removing the deposited film may not be required. Instead, the deposited film may be removed using a relatively simple cleaning process. A suitable cleaning process may, for example, be one that provides a relatively small etchability or a ZETA cleaning method that uses a cleaning solution such as SC-1. SC-1 and ZETA cleaning methods are well known to the art, and need not be explained in greater detail.

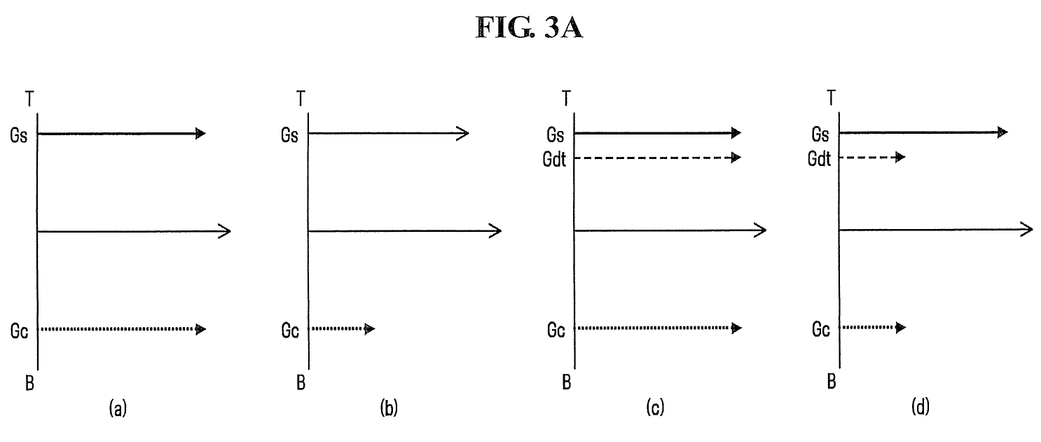

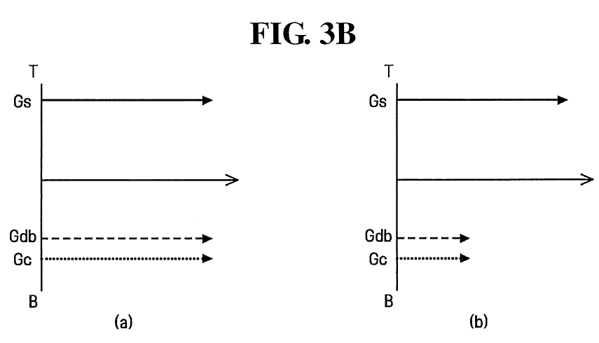

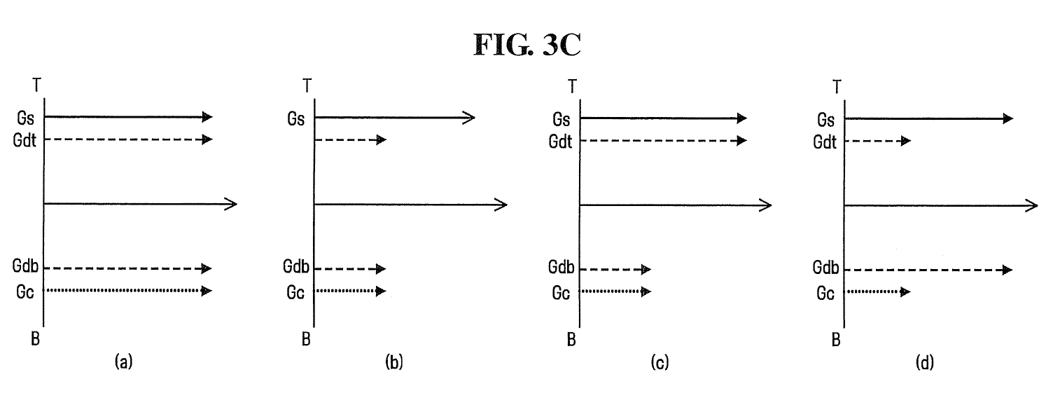

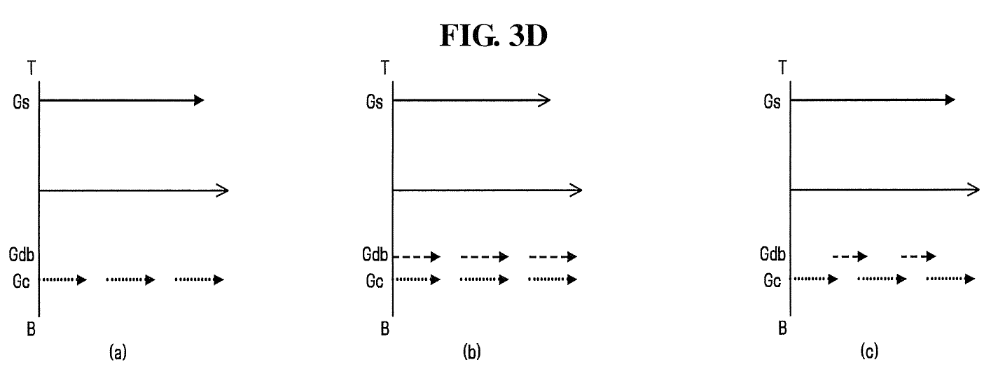

FIGS. 3A through 3D are visual illustrations of various gas supply methods according to the present invention. An X-axis of each graph indicates a period of time during which a plasma ion doping process is performed, and a Y-axis indicates a position at which gas is injected into a reaction chamber. A lower (e.g. bottom) part B may not necessarily denote a direction from bottom to top and may denote gas supply directions relatively lower than an upper (e.g. top) part T. That is, the lower part B may denote parts or directions in which gas is supplied from positions lower than the upper part T from which gas is supplied from the upper part of the reaction chamber.

Referring to FIG. 3A, graph (a) represents a process in which an ion doping source gas Gs is supplied from the upper part T of the reaction chamber and a control gas Ge is supplied from the lower part B to perform a plasma ion doping process. Graph (b) represents a process in which the ion doping source gas Gs is continuously supplied from the upper part T while the supply of the control gas Gc is suspended after the control gas Gc is supplied from the lower part B. Graph (c) represents a process in which a diluent gas Gdt is supplied from the upper part T, and graph (d) represents a process in which the supply of both of the diluent gas Gdt and the control gas Gc is suspended after they are supplied for a predetermined period of time.

The graphs (a) to (d) illustrated in FIG. 3A indicate positions from which gas is supplied, but do not indicate flux, pressure, temperature and other processing conditions. Duration of the plasma ion doping process need not necessarily be proportional to the length of an arrow. It should be understood that the illustrated embodiments are examples, and do not represent absolute processing recipes.

Referring to FIG. 3B, graph (a) represents a process in which the diluent gas Gdb is supplied from the lower part B, and graph (b) represents a process in which the supply of the diluent gas Gdb and the control gas Gc are suspended after they are supplied for a predetermined period of time.

Referring to FIG. 3C, graph (a) represents a process in which the diluent gases Gdt and Gdb are supplied from the upper part T and the lower part B, respectively. Graph (b) represents a process in which the control gas Gc and the diluent gases Gdt and Gdb are supplied for a predetermined period of time, and graph (c) represents a process in which the ion doping source gas Gs and the diluent gas Gdt are continuously supplied from the upper part T while the control gas Gc and the diluent gas Gdb are supplied from the lower part B for a predetermined period of time. Graph (d) represents a process in which the diluent gas Gdb is continuously supplied from the lower part B while the diluent gas Gdt and the control gas Gc are supplied from the upper part T for a predetermined period of time.

Referring to FIG. 3D, gas supply from the lower part B is repeatedly resumed and suspended. Specifically, graph (a) represents a process in which the supply of the control gas Gc is repeatedly resumed and suspended, and graph (b) represents a process in which the supply of the control gas Gc and the diluent gas Gdb is repeatedly resumed and suspended. In addition, graph (c) represents a process in which the supply of the control gas Gc and the diluent gas Gdb is repeatedly resumed and suspended in different cycles.

Numerous recipes other than the processing recipes illustrated in FIGS. 3A through 3D may be applied. In the illustrated examples, an ion doping source gas is supplied from upper parts of the reaction chamber, and a control gas is supplied in lower parts of the reaction chamber. However, the gases may be supplied in various ways. It will be understood, for example, that third and fourth gases can further be supplied using various techniques. A combination processes is simple in concept but varied in detail.

Table 1 shows results of performing three processes selected from various combinations of processes according to some embodiments of the present invention.

TABLE 1

| | CET | | Resistance (Ω) | | Vth(L)(mV) | | Vth(D/R)(mV) | |
|---|---|---|---|---|---|---|---|---|
| P1 | Avg. | 34.4 Å | Min | 39 | (N)Rng. | 10~20 | (N)Rng. | 3~20 |
| | Unif. | 0.4~0.6% | Max | 113 | (P)Rng. | 20~23 | (P)Rng. | 12~37 |
| P2 | Avg. | 33.5 Å | Min | 60 | (N)Rng. | 13~26 | (N)Rng. | 3~20 |
| | Unif. | 0.3~0.5% | Max | 129 | (P)Rng. | 19~28 | (P)Rng. | 10~40 |
| P3 | Avg. | 33.5 Å | Min | 57 | (N)Rng. | 8~14 | (N)Rng. | 5~24 |
| | Unif. | 0.2~0.5% | Max | 346 | (P)Rng. | 14~25 | (P)Rng. | 14~64 |

In a process P1, an ion doping source gas was supplied from an upper part of a reaction chamber while a control gas was supplied from a lower part. The process P1 may be viewed as corresponding to the process represented by graph (a) of FIG. 3A.

In a process P2, the ion doping source gas was supplied from the upper part of the chamber while the control gas was supplied from the lower part in an initial stage of the plasma ion doping process. Then, the supply of the control gas from the lower part was suspended while the ion doping source gas was continuously supplied from the upper part in a later stage of the plasma ion doping process. The process P2 may be viewed a corresponding to the process represented by graph (b) of FIG. 3A.

In a process P3, the ion doping source gas and a diluent gas were supplied from the upper part of the chamber while the control gas was supplied from the lower part. The process P3 may be viewed as corresponding to the process represented by graph (c) of FIG. 3A.

In these example processes, a BF₃ gas was used as the ion doping source gas, and a SiH₄ gas was used as the control gas. In addition, each of the three plasma ion doping processes was performed for 120 seconds using an electric field of 7.8 KV.

Referring to Table 1, better processing performance appears to have been achieved when measured values of capacitance of electrical thickness of oxide (CET) and resistance were lower and had smaller deviations. In addition, when a threshold voltage (Vth) was maintained at an appropriate level and had a smaller deviation, better processing performance appears to have been achieved. Although each processing recipe had advantages and disadvantages, the process P2 process appears to provide generally superior performance.

However, because Table 1 shows data on an experiment conducted under certain conditions, the data should not be understood as being absolute. When different equipment and different gases are used, different results may be obtained.

Table 2 summarizes results of performing various combinations of processes according to some embodiments of the present invention.

TABLE 2

| Process | Gas Supply (sccm) | | Thickness of Deposited Film (Å) | | | Sheet Resistance (Ω) | |
|---|---|---|---|---|---|---|---|
| Name | upper | lower | Average | Range | Deviation | Average | Deviation |
| S1 | 15 SiH₄ | — | 746 | 66 | 2.79 | 1429 | 4.13 |
| S2 | 15 SiH₄ | 200 SiH₄ | 800 | 40 | 2.4 | 1363 | 2.98 |
| S3 | — | 200 SiH₄ | 772 | 68 | 2.45 | 1356 | 1.37 |
| S4 | 50 He | 200 SiH₄ | 749 | 37 | 1.49 | 1352 | 0.68 |

In a process S1, a control gas was supplied from an upper part of a reaction chamber. In a process S2, the control gas was supplied in both upper and lower parts of the reaction chamber.

In a process S3, the control gas was not supplied from the upper part of the reaction chamber and was supplied from the lower part of the chamber. In a process S4, a diluent gas was supplied from the upper part of the chamber while the control gas was supplied from the lower part. A BF₃ gas was used as an ion doping source gas in all of the processes.

When it comes to the thickness of a film deposited by the control gas and sheet resistance (Rs), the S4 process showed more desirable characteristics. Because it is desirable to remove the film deposited by the control gas, it may be preferable that the film is thinner and has smaller deviation. In addition, the lower sheet resistance and the smaller deviation may be more desirable.

It was learned from various experiments that different results having advantages and disadvantages may be obtained if various processes are combined. Accordingly, it may be possible to achieve better results when various control gases are supplied from upper and lower parts of a reaction chamber while a depositing gas was supplied from a lower part of the chamber and a diluent gas was supplied from the upper part of the chamber.

Better results may be achieved when a more complete equipment system is provided. That is, if a plasma ion doping apparatus, which can supply various gases from various parts, is provided, various experiments can be conducted by varying the location from which gas is supplied, and the amount of gas supplied. Therefore, the above-described experimental results should not be construed as limiting the scope of the present invention.

Hereinafter, a plasma ion doping apparatus according to further embodiments of the present invention will be described.

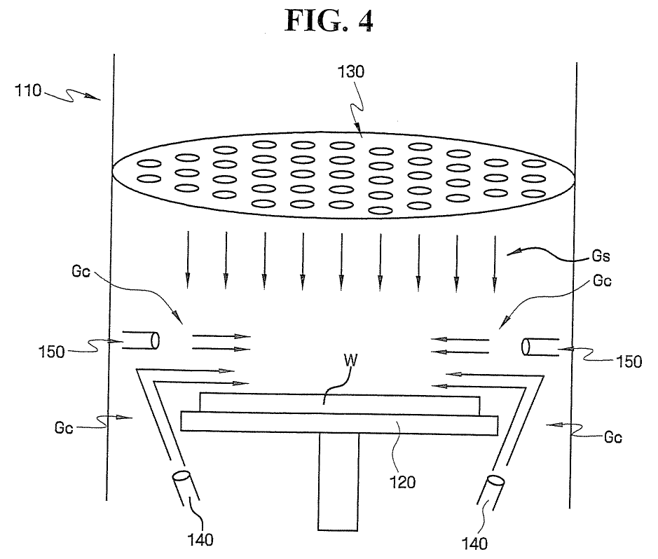

FIG. 4 is a schematic diagram illustrating a plasma ion doping apparatus according to some embodiments of the present invention. Referring to FIG. 4, the plasma ion doping apparatus includes a reaction chamber 110, a susceptor 120, a shower head 130, a lower gas inlet 140 and/or a lateral gas inlet 150. The chamber 110 provides a sealed space in which a plasma ion doping process is performed. A wafer W is mounted on the susceptor 120, and the plasma ion doping process is performed on the wafer W.

The shower head 130 is located in an upper part of the reaction chamber 110 and serves as a passage through which an ion doping source gas Gs is supplied. The lower gas inlet 140 may supply a control gas Gc. The control gas Gc supplied through the lower gas inlet 140 may be a depositing gas and/or a diluent gas. The lower gas inlet 140 may also be used as a passage through which a gas for a seasoning process is supplied. A seasoning process may be performed using a dummy wafer, which is introduced into the reaction chamber 110 before a normal plasma ion doping process is performed and after the reaction chamber 110 is cleaned. The seasoning process may be performed in order to create an environment suitable for performing plasma ion doping processes within the reaction chamber 110.

The lateral gas inlet 150 may also supply a control gas Gc. The lateral gas inlet 150 may be designed as a passage for supplying a gas that is identical to or different from a gas supplied through the lower gas inlet 140. That is, the lateral gas inlet 150 may be used to supply a gas that is also supplied through the lower gas inlet 140 or to supply a gas that is different from the gas supplied through the lower gas inlet 140. For example, a diluent gas may be supplied through the lower gas inlet 140 and a depositing gas may be supplied through the lateral gas inlet 150, or the vice versa. The lower gas inlet 140 and/or the lateral gas inlet 150 may each include, for example, a miniaturized showerhead. The control gas Gc supplied through the lower gas inlet 140 or the lateral gas inlet 150 may maintain a horizontal flow on a surface of the wafer W.

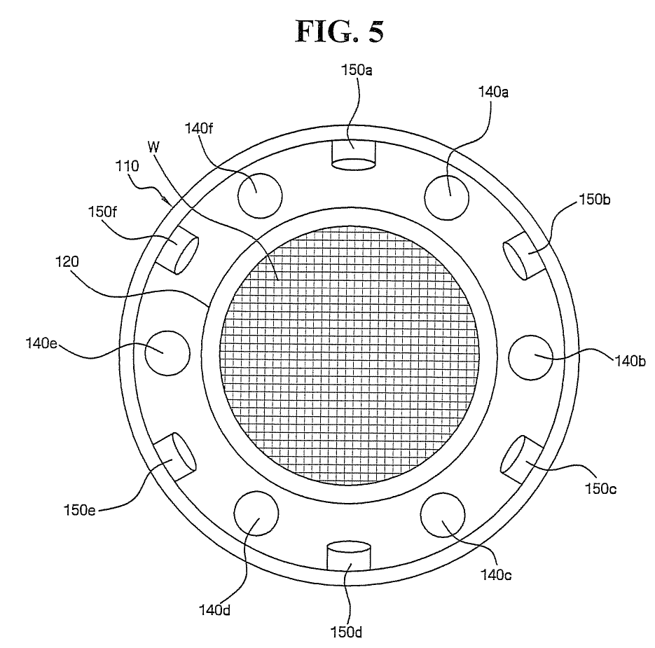

FIG. 5 is a diagram illustrating various arrangements of gas inlets included in a plasma ion doping apparatus according to further embodiments of the present invention. Referring to FIG. 5, the plasma ion doping apparatus includes a reaction chamber 110, a susceptor 120 on which a wafer W can be mounted, a plurality of lower gas inlets 140a-140f and/or a plurality of lateral gas inlets 150a-150f. Particular shapes or rates illustrated herein should not be construed as limiting the scope of the present invention.

The lower gas inlets 140a-140f and/or the lateral gas inlets 150a-150f are arranged on a wall of the reaction chamber 110, around the susceptor 120, and in a radial fashion. The lower gas inlets 140a-140f and/or the lateral gas inlets 150a-150f may be located in a particular directions or parts of the chamber other than the radial arrangement, so that gas can flow on the wafer W in one or more particular directions. In FIG. 5, because gas can be injected into the reaction chamber 110 in a radial manner, and gas may flow on the wafer W in radial directions. Although not shown in the FIG. 5, an exhaust may form a flow for exhausting gas on the wafer W. In addition, because the susceptor 120 may rotate, a spiral gas flow may be provided on the wafer W.

In further embodiments, gas inlets may be located in particular directions. For example, gas inlets a-c in FIG. 5 may be provided. In such embodiments, the gas flow formed on the wafer W may be in only one or a few directions. When the gas flow is predominantly in one direction, different experimental results may be produced as compared to when a spiral gas flow is provided.

As described above, the lateral gas inlets 150a-150f may be located adjacent to a surface of the wafer W in order to inject gas into a sheath region and/or may be positioned to supply gas to a lower region of a plasma region. In some embodiments, the lateral gas inlets 150a-150f may be arranged to perform the above two functions.

As described above, plasma ion doping according to some embodiments of the present invention may precisely control ion doping concentration by forming a porous, thin or sparse deposited film using a deposition control gas. In addition, because the deposited film may be relatively easily removed, its removal does not adversely affect performance of a semiconductor device formed using such a process.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A plasma ion doping method comprising:
mounting a wafer on a susceptor within a reaction chamber; and
plasmalyzing an ion doping source gas introduced into an upper part of the reaction chamber above a major surface of the wafer while supplying a control gas into the reaction chamber in a lower part of the reaction chamber opposite the major surface of the wafer to thereby dope ions into the major surface of the wafer.

2. The method of claim 1, wherein plasmalyzing an ion doping source gas introduced into an upper part of the reaction chamber above a major surface of the wafer while supplying a control gas into the reaction chamber in a lower part of the reaction chamber opposite the major surface of the wafer to thereby dope ions into the major surface of the wafer comprises plasmalyzing the ion doping source and supplying the control gas in the presence of an electric field directed substantially perpendicular to the major surface of the wafer.

3. The method of claim 1, wherein the ion doping source gas comprises at least one halide gas.

4. The method of claim 1, wherein the control gas comprises at least one depositing gas.

5. The method of claim 4, wherein the at least one depositing gas comprises a silane gas.

6. The method of claim 1, further comprising flowing a diluent gas into the reaction chamber while supplying the ion doping source gas and the control gas.

7. The method of claim 6, wherein the diluent gas is supplied to the upper part of the reaction chamber.

8. The method of claim 6, wherein the diluent gas comprises an inert gas.

9. The method of claim 1, comprising flowing the control gas horizontally across the major surface of the wafer.

10. The method of claim 9, further comprising flowing the control gas into a sheath region.

11. The method of claim 9, further comprising radially or spirally flowing the control gas flows across the major surface of the wafer.

12. A plasma ion doping method comprising:
mounting a wafer on a susceptor within a reaction chamber; and
plasmalyzing an ion doping source gas introduced into an upper part of the reaction chamber above a major surface of the wafer while flowing a control gas laterally across the major surface of the wafer to thereby dope ions into the wafer.

13. The method of claim 12, wherein plasmalyzing an ion doping source gas introduced into an upper part of the reaction chamber above a major surface of the wafer while flowing a control gas laterally across the major surface of the waver to thereby dope ions into the wafer comprises plasmalyzing the ion doping source gas and flowing the control gas laterally across the major surface of the waver in the presence of an electric field directed substantially perpendicular to the major surface of the wafer.

14. The method of claim 12, wherein flowing a control gas comprises flowing the control gas into a plasma region above the major surface of the wafer.

15. The method of claim 12, wherein flowing a control gas comprises flowing the control gas into a sheath region.

16. The method of claim 12, wherein plasmalyzing an ion doping source gas into the reaction chamber in an upper part of the reaction chamber above a major surface of the wafer while flowing a control gas laterally across the major surface of the waver to thereby dope ions into the wafer comprises plasmalyzing the ion doping source gas into the reaction chamber in an upper part of the reaction chamber above a major surface of the wafer while flowing the control gas laterally across the major surface of the waver and supplying a diluent gas to the upper part of the reaction chamber.

17. A plasma ion doping apparatus comprising:
a reaction chamber;
a susceptor disposed in the reaction chamber and configured to hold a wafer;
a shower head disposed in an upper part of the reaction chamber and configured to supply a plasma ion doping source gas above a major surface of a wafer mounted on the susceptor; and
lower gas inlets configured to supply a control gas laterally onto a wafer mounted on the susceptor.

18. The apparatus of claim 17, further comprising lateral gas inlets configured to flow a gas across the major surface of a wafer mounted on the susceptor.

19. The apparatus of claim 17, wherein the lateral gas inlets are disposed above the susceptor.

20. The apparatus of claim 18, wherein the lower gas inlets are radially disposed around the susceptor.
